(19) United States
(12) Patent Application Publication
(10) Pub. No.: US 2022/0352363 A1
(43) Pub. Date: Nov. 3, 2022

(54) MICROELECTRONIC DEVICE

(71) Applicant: COMMISSARIAT A L'ENERGIE ATOMIQUE ET AUX ENERGIES ALTERNATIVES, Paris (FR)

(72) Inventors: Julien BUCKLEY, Grenoble Cedex 09 (FR); Blend MOHAMAD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/730,474

(22) Filed: Apr. 27, 2022

(30) Foreign Application Priority Data
Apr. 30, 2021 (FR) 21 04559

(51) Int. Cl. H01L 29/778; H01L 29/423; H01L 29/51

(52) U.S. Cl. CPC H01L 29/7788; H01L 29/42364; H01L 29/517

(57) ABSTRACT

A GaN-based power transistor including:
a stack of layers in a vertical direction (z), the stack including, from an upper surface of the stack:
   a first AlGaN-based barrier),
   a GaN-based layer, and
   a second AlGaN-based barrier; and
a gate pattern including:
   a metal gate, and
   a gate dielectric electrically insulating the metal gate from the stack, the metal gate being in contact with a bottom part and a wall part of the gate dielectric,
the gate pattern passing through the first AlGaN-based barrier, then totally passing through the GaN-based layer and at least partially through the second AlGaN-based barrier, in the vertical direction (z), such that the second AlGaN-based barrier has a concentration of aluminium [Al]2 of less than or equal to 8% at.

### TECHNICAL FIELD

The present invention relates to the field of microelectronics. It has a particularly advantageous application in the production of GaN-based power transistors. An example of a particular application relates to two-dimensional electron gas (2 DEG) GaN transistors.

### STATE OF THE ART

In the field of power electronics, a significant challenge relates to the development of “large gap” semiconductor-based power transistors, such as GaN.

Different architectures have been specifically developed for these GaN-based transistors. The architectures based on the use of a two-dimensional electron gas (2 DEG), typically making it possible to operate with high source-drain polarisation voltages. A positive threshold voltage advantageously makes it possible to simplify the control circuit of the transistor and to ensure the safety of the conversion system in the event of a failure.

The document “Miyamoto et al., Jpn. J. Appl. Phys. 59 044002, 2020” discloses a 2DEG GaN transistor with a positive threshold voltage. This transistor comprises a stack of layers in a vertical direction (z) comprising, from an upper surface of said stack:
A first AlGaN-based barrier,
A GaN-based channel,
A second AlGaN-based barrier.

This transistor further comprises a gate pattern comprising:
A metal gate
A gate dielectric separating the metal gate from the layers of said stack.

The GaN-based channel is comprised between the first and second AlGaN-based barriers, and the gate pattern of this transistor passes through the first AlGaN-based barrier and leads to its lower end within the GaN-based channel. In this architecture, the two-dimensional electron gas is formed by piezoelectric and spontaneous polarisation effect under the first AlGaN-based barrier, on either side of the gate pattern. The application of a source-gate voltage Vgs greater than the threshold voltage Vth makes it possible for the electrons to circulate in the channel. The threshold voltage is here made positive by the presence of the second AlGaN-based barrier, by a simple electrostatic effect.

A disadvantage of this solution is that the value of the threshold value is relatively low (<1V) which can require controlling the off transistor with a value Vgs<0. The application of a voltage Vgs<0 involves resorting to a more complex control circuit. Moreover, it has proven to be, that with this solution, the resistance of the transistor to the on-state increases. This degrades the electrical current 6 at the on-state.

Furthermore, a positive threshold voltage transistor architecture III-V is known from patent application JP 2008010803 A1. It has a very specific operation due to the structure of the gate pattern wherein the lateral wall of the metal gate is not in contact with the gate dielectric.

Moreover, architectures of power transistors based on a two-dimensional electron gas are known from patent documents US 20110068371 A1 et US 20140264273 A1, wherein the gate pattern passes through a plurality of alternances of AlGaN layers and of GaN layers. In their operation, the transistors of these two patent applications aim to decrease the resistance over a horizontal conduction path and the second barrier must provide charge carriers. Controlling the electrical current Iₒₙ at the on-state is made more complex.

There is therefore a need consisting of proposing a 2DEG GaN power transistor architecture overcoming the disadvantages mentioned above.

An aim of the present invention is to propose a GaN-based power transistor having a positive and sufficiently high threshold voltage Vth, typically Vth>1V and preferably Vth>2V.

The other aims, characteristics and advantages of the present invention will appear upon examining the following description and the accompanying drawings. It is understood that other advantages can be incorporated.

### SUMMARY

To achieve this aim, according to an embodiment, a GaN-based power transistor is provided, comprising a stack of layers in a vertical direction (z), said stack comprising, from an upper surface of said stack:
A first AlGaN-based barrier.
A GaN-based layer,
A second AlGaN-based barrier.

This transistor further comprises a gate pattern comprising:
A metal gate
A gate dielectric electrically insulating the metal gate from the stack.

The gate pattern of the transistor passes through the first AlGaN-based barrier.

Advantageously, the gate pattern of the transistor totally passes through the GaN-based layer and at least partially through the second AlGaN-based barrier. The lower end of the gate pattern leads to said second AlGaN-based barrier, or under said second AlGaN-based barrier, for example in a second GaN-based layer forming a conduction channel. There is thus an intersection between the gate pattern and the second AlGaN-based barrier.

The polarisation voltage Vgs necessary for the passage of electrons around the gate pattern is thus increased. The threshold voltage Vth beyond which the transistor is in the on-state is significantly increased.

This increase of Vth is initially induced by the physical barrier formed by the second AlGaN-based barrier for the passage of electrons. The threshold voltage is no longer only modulated by electrostatic repulsion effect, as is the case in the transistor disclosed by the solution of the prior art. On the contrary, the threshold voltage is here increased from an additional potential barrier to be crossed.

The threshold voltage also secondly benefits from the electrostatic repulsion effect induced at the proximity of the second AlGaN-based barrier.

A synergy effect is thus obtained between the first overriding effect, linked to the crossing of the second barrier itself, and the second minor effect, linked to the electrostatic repulsion surrounding said second barrier.

The principle of increasing Vth on which the present invention is based is thus fundamentally different from the principle on which the solution of the prior art is based.

The transistor according to the present invention thus has a threshold voltage Vth significantly higher than that of the transistor according to the prior art.

Moreover, during the development of the present invention, it is clear that the increase in resistance at the on-state observed by implementing the solution of the prior art was due to the proximity of the second AlGaN-based barrier as regards the first AlGaN-based barrier. The two-dimensional electron gas formed under the first AlGaN-based barrier is indeed depleted by the electrostatic field around the second barrier. Thus, the closer the second barrier is to the first barrier, the more depleted the two-dimensional electron gas is, and the more the resistance at the on-state increases.

According to the present invention, the gate pattern is extended by depth at least up to the second barrier. This advantageously makes it possible to extend the second barrier from the first barrier, so as to limit, even remove the depletion of the two-dimensional electron gas formed under the first AlGaN-based barrier. According to an example, the second AlGaN-based barrier is separated from the first AlGaN-based barrier by a GaN layer of thickness greater than or equal to 50 nm, preferably greater than or equal to 100 nm. This makes it possible to significantly limit the increase in resistance at the on-state of the transistor. Preferably, a concentration of aluminium less than or equal to 8% at is used for the second barrier. In this configuration, the second barrier plays a particular role, in that it forms a potential barrier passed through by charge carriers; a concentration of aluminium which is too high would not make it possible to pass through this potential barrier vertically along the side of the gate pattern. In this sense, the operation obtained by the power transistor according to the present invention is opposite that sought in publications US 20110068371 A1 and US 20140264273 A1.

### BRIEF DESCRIPTION OF THE FIGURES

The aims, objectives, as well as the characteristics and advantages of the invention will best emerge from the detailed description of embodiments of the letter, which are illustrated by the following accompanying drawings, wherein:

FIG. 1 schematically illustrates a transistor according to a first embodiment of the present invention.

FIG. 2 schematically illustrates a transistor according to a second embodiment of the present invention.

FIG. 3 schematically illustrates a transistor according to a third embodiment of the present invention.

FIG. 4 schematically illustrates a transistor according to a fourth embodiment of the present invention.

FIG. 5 has an evolutionary curve of the threshold voltage Vth of the gate of the transistor according to the concentration of aluminium [Al]2 in the second AlGaN-based barrier.

FIG. 6 presents an evolutionary curve of the threshold voltage Vth of the gate of the transistor according to the thickness e12 of the second AlGaN-based barrier.

The drawings are given as examples and are not limiting of the invention. They constitute schematic principle representations intended to facilitate the understanding of the invention and are not necessarily to the scale of the practical applications. In particular, on the principle diagrams, the thicknesses of the different layers, and the dimensions of the different patterns (gate, source, drain, etc.) are not representative of reality.

### DETAILED DESCRIPTION

Before starting a detailed review of embodiments of the invention, optional characteristics are stated below, which can possibly be used in association or alternatively:

According to an example, the GaN-based layer and the second AlGaN-based barrier are in contact with one another at an interface plane, and the gate pattern forms an intersection with said interface plane. The intersection between the gate pattern and the interface plane extends in particular in the mechanical sense. According to an example, only the gate dielectric forms an intersection with the interface plane. According to an example, the gate dielectric and the metal gate each form an intersection with said interface plane.

According to an example, the gate pattern totally passes through the second AlGaN-based barrier in the vertical direction z. According to an example, the metal gate of the gate pattern has an end at a basal plane parallel to the interface plane and passing within the second AlGaN-based barrier.

According to an example, the metal gate of the gate pattern has an end at a basal plane parallel to the interface plane and passing within the GaN-based layer.

According to an example, the metal gate of the gate pattern has an end located at a depth d210 and the second AlGaN-based barrier has a surface located at a depth d12, such that d210<d12, said depths d210 and d12 being taken in the vertical direction from a reference plane passing through the upper surface of the stack.

According to an example, the metal gate of the gate pattern has an end located at a depth d210 and the second AlGaN-based barrier has a surface located at a depth d12, such that d210>d12, said depths d210 and d12 being taken in the vertical direction from a reference plane passing through the upper surface of the stack.

According to an example, the metal gate of the gate pattern has an end located at a depth d210 and the GaN-based layer has a surface located at a depth d10, such that d210<d10, said depths d210 and d10 being taken in the vertical direction from a reference plane passing through the upper surface of the stack.

According to an example, the metal gate of the gate pattern has an end located at a depth d210 and the GaN-based layer has a surface located at a depth d10, such that d210>d10, said depths d210 and d10 being taken in the vertical direction from a reference plane passing through the upper surface of the stack.

According to an example, the gate pattern has an end located at a depth d20 and the second AlGaN-based barrier has a surface located at a depth d12, such that d20<d12, said depths d20 and d12 being taken in the vertical direction from a reference plane passing through the upper surface of the stack.

According to an example, the gate pattern has an end located at a depth d20 and the second AlGaN-based barrier has a surface located at a depth d12, such that d20>d12, said depths d20 and d12 being taken in the vertical direction from a reference plane passing through the upper surface of the stack.

According to an example, the second AlGaN-based barrier has a concentration of aluminium [Al]2 less than or equal to 8% at, and preferably of between 2% at and 8% at. According to a possibility, this concentration is constant within the second barrier; in particular, it does not vary according to the thickness of the latter, nor transversally to the thickness.

According to an example, the concentration of aluminium [Al]2 has a Gaussian profile in the vertical direction. This makes it possible to make the second barrier less steep for the passage of the two-dimensional electron gas. The current of the transistor at the on-state Iₒₙ is thus less degraded.

According to an example, the second AlGaN-based barrier has a gradient of concentration of aluminium [Al]2(z) in the vertical direction. In particular, outside of the Gaussian profile, there can be a monotonous variation of concentration [Al]2 in the vertical direction; the minimum concentration can be located at the interface between the GaN-based layer and the second AlGaN-based barrier.

According to an example, the second AlGaN-based barrier has a thickness e12 taken in the vertical direction of between 20 nm and 50 nm.

According to an example, the second AlGaN-based barrier comprises a plurality of layers arranged in a superlattice. Said plurality of layers can form quantum wells.

According to an example, the transistor further comprises a source and a drain on either side of the gate pattern, said source totally passing through the second AlGaN-based barrier in the vertical direction.

Except if incompatible, technical characteristics described in detail for a given embodiment can be combined with the technical characteristics described in the context of other embodiments described as examples and in a non-limiting manner, so as to form another embodiment which is not necessarily illustrated or described. Such an embodiment is, of course, no excluded from the invention.

In the scope of the present invention, the power transistor architectures considered are typically with lateral conduction, between a source and a drain, and more specifically, based on a two-dimensional electron gas (2 DEG) conduction principle.

Such a transistor architecture includes the superposition of two semiconductive layers having different band gaps which form a quantum well at their interface. This quantum well is induced by the present spontaneous and piezoelectric polarisation charges. Electrons are confined in this quantum well to form a two-dimensional electron gas.

HEMT (High Electron Mobility Transistor)-type transistors, which means field effect transistor with high electron mobility), also sometimes referenced by the term of heterostructure field effect transistor, are examples of transistors based on this two-dimensional electron gas architecture.

For power handling (in particular, high voltage) and temperature handling reasons, the semiconductive material of these transistors is chosen so as to have a wide energy band gap. Among wide energy band gap HEMT transistors, gallium nitride-based transistors are very promising.

With a lateral conduction transistor, the gate/drain breakdown voltage can easily be controlled by a suitable distance between gate and drain. A breakdown voltage of around 600V can thus be reached for a distance between the gate and the drain of the transistor of a few microns (6 to 15 μm, for example). In addition, such transistors enable very large current densities, due to the very high electronic mobility and the high electronic density in the interface electron gas.

In the scope of the present invention, the passage of the current is typically controlled by a gate polarised positively relative to the source.

This gate can be of the MOS or MOSFET (Metal Oxide Semiconductor Field Effect Transistor)-type. In this case, the metal gate is electrically insulated from the semiconductive layers by a gate dielectric. Other gate compositions can be considered. A particularity of the transistor architectures according to the present invention is that the gate passes through the quantum well at which the two-dimensional electron gas is confined. The continuity of the two-dimensional electron gas is thus broken by a trench wherein the MOS gate of the transistor is produced.

Generally, if the gate of the transistor is set to a voltage greater than a threshold voltage, there is an accumulation of electrons under the gate dielectric, thus connecting the two-dimensional electron gas on either side of it, which makes it possible to connect the source and the drain such that the transistor becomes an “on” transistor.

If the gate of the transistor is set at a voltage less than the threshold voltage, the source and the drain are no longer connected and the transistor is called an “off” transistor.

The components having a positive threshold voltage are called “normally-off”. The invention applies more specifically to 2DEG normally-off power transistors.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer covers at least partially the second layer by being either directly in contact with it, or by being separated from it by at least one other layer or at least one other element.

For example, and in a manner known per se in the field of GaN-based HEMT-type transistors, a thin AlN layer can be interposed between two GaN and AlGaN semiconductive layers.

A layer can moreover be composed of several sublayers made of one same material or of different materials.

By a material A-“based” substrate, stack, layer, this means a substrate, a stack, a layer comprising this material A only or this material A and possibly other materials, for example alloy elements and/or doping elements.

The doping ranges associated with the different doping types indicated in the present application are as follows:
p++ or n++ doping: greater than 1×10²⁰ cm⁻³
p+ or n+ doping: 1×10¹⁸ cm⁻³ to 9×10¹⁹ cm⁻³
p or n doping: 1×10¹⁷ cm⁻³ to 1×10¹⁸ cm⁻³
intrinsic or unintentionally doped doping: around n·10¹⁵ cm⁻³ or below (n being typically of between 1 and 9).

A preferably orthonormal marker, comprising the axes x, y, z is represented in the accompanying figures. When one single marker is represented on one same set of figures, this marker applies to all the figures of this set.

In the present patent application, the thickness of a layer is taken in a direction normal to the main extension plane of the layer. Thus, a layer typically has a thickness along z. The relative terms “on”, “surmounts”, “under”, “underlying” refer to positions taken in the direction z.

The terms “vertical”, “vertically” refer to a direction along z. The terms “horizontal”, “horizontally” refer to a direction in the plane xy.

An element located “vertically aligned with” or “to the right of” another element means that these two elements are both located on one same line perpendicular to a plane wherein a lower or upper face of a substrate mainly extends, i.e. on one same line oriented vertically in the figures.

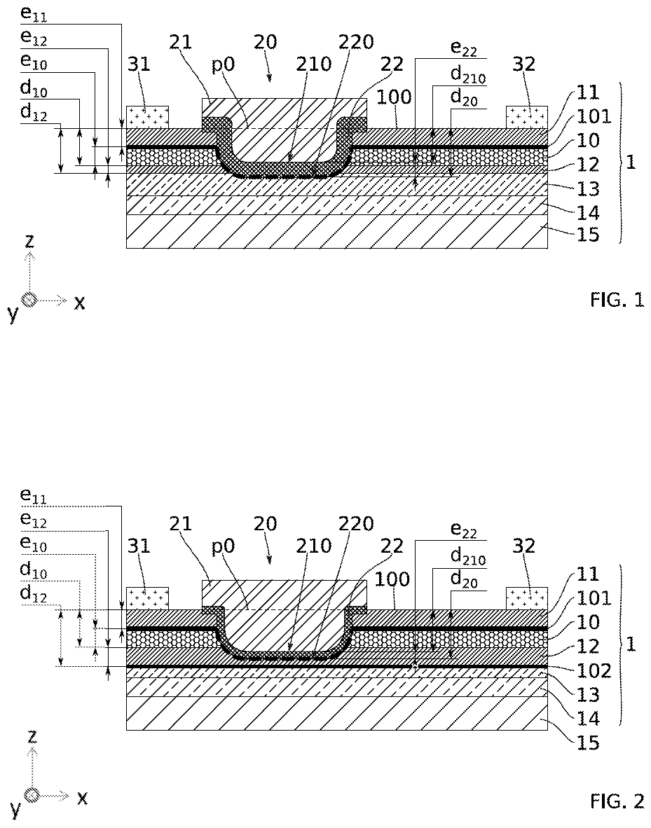

Examples of transistors according to the present invention are illustrated in FIGS. 1 to 4. The general architecture of these transistors comprises a source 31 and a drain 32 formed on either side of a gate pattern 20. The gate pattern 20 extends partially through a stack 1 of layers 10, 11, 12, 13, 14 formed on a substrate 15. General characteristics of these transistors, common to all the embodiments, are indicated below. The characteristics specific to each embodiment are detailed below.

The substrate 15 can be a silicon-based substrate (111). Alternatively, the substrate 15 can be sapphire or SiC-based. Known GaN on sapphire or GaN on silicon substrates can typically be used.

The stack 1 can comprise a plurality of layers with the basis of epitaxial materials III-V on the substrate 15. The stack 1 thus typically comprises, starting with the substrate 15 and in the direction z:
One or more so-called buffer layers 14. These layers 14 have the objective of improving the crystalline quality of the upper layers. They can, for example, allow the differences in mesh parameters between the materials III-V used and the substrate, and/or withstand the plastic relaxation induced by the different sources of mechanical stresses, and/or limit the appearance or the transmission of crystalline defects.
An unintentionally doped GaN layer 13.
The second AlGaN-based barrier 12. The second AlGaN-based barrier 12 has a thickness e12 of between 20 nm and 50 nm.
The GaN-based layer 10 is unintentionally doped. The GaN-based layer 10 has a thickness e10, for example of between 50 nm and 200 nm.
The first AlGaN-based barrier 11. The first AlGaN-based barrier 11 has a thickness e11, for example of between 20 nm and 100 nm.

The different epitaxial layers, in particular the first and second barriers 11, 12 and the GaN-based layer 10, can be very specifically controlled by thickness. A variability less than 0.5 nm by thickness is typically obtained for these epitaxial layers. This ultimately makes it possible to specifically control the distances separating the different layers and the targeted electrostatic effects.

The second AlGaN-based barrier 12 typically comprises an aluminium ratio [Al]2 of between 2% at. and 8% at. A ratio [Al]2 less than or equal to around 8% at. makes it possible to preserve a mesh parameter compatible with a GaN epitaxy of crystalline quality required for the transistor. The GaN-based layer 10 can thus be epitaxial on the 30 second AlGaN-based barrier 12 by limiting the appearance of crystalline defects. A high aluminium ratio can decrease the current passing through the second barrier 12.

According to a possibility, the second AlGaN-based barrier 12 has a gradient of concentration of aluminium [Al]2(z) along z. For example, [Al]2(z) has a Gaussian profile centred over half of the thickness e12 of the second barrier 12. This makes it possible to limit a steep barrier effect. The current at on-state L is thus less degraded.

In this stack 1, a two-dimensional electron gas 101 is formed under the first AlGaN-based barrier 11, in the GaN-based layer 10. The two-dimensional electron gas 101 is typically confined at the interface between the first AlGaN-based barrier 11 and the GaN-based layer 10.

The gate pattern 20 passes through this interface between the first AlGaN-based barrier 11 and the GaN-based layer 10, so as to interrupt the two-dimensional electron gas 101. Controlling the gate voltage Vgs makes it possible to enable or block the passage of electrons of the two-dimensional electron gas 101 on either side of the gate pattern 20. The gate pattern 20 comprises a metal gate 21 and a gate dielectric 22 separating the metal gate 21 of the stack 1. As represented in FIGS. 1 to 4, the gate pattern 20 comprises a metal gate 21 in contact with the gate dielectric 22. It is the gate dielectric 22 which produces the interface relative to the layers of the stack 1. The metal gate 21 and the gate dielectric 22 have a depth extension such that the pattern 20 extends into the thickness of the stack 1. In this context, these two elements have a shape such that they have a bottom part (as shown by the end 210 and the end 220 which can be seen in FIGS. 1 to 4; the bottom part can be directed at least partially along a plane parallel to the reference plane p0) and a wall part, or also sides extending at least partially, and preferably at least mainly, along a plane perpendicular to the reference plane p0. The bottom parts of the gate 21 and of the gate dielectric 22 are in contact with one another. The wall parts of the gate 21 and of the gate dielectric 22 are in contact with one another.

The metal gate 21 and the dielectric 22 are therefore in contact on their bottom and on their side.

The gate pattern 20 has a lower end 220, which corresponds to the lower end 220 of the gate dielectric 22, and this lower end 220 is located at a depth d20 along z relative to the reference plane p0. The metal gate 21 has a lower end 210 located at a depth d210 along z relative to the reference plane p0. The lower surface of the second barrier 12 is located at a depth d12 along z relative to the reference plane p0. The lower surface of the GaN-based layer 10, which corresponds to the upper surface of the second barrier 12, is located at a depth d10 along z relative to the reference plane p0.

The gate pattern 20 totally passes through the GaN-based layer 10, and at least partially through the second AlGaN-based barrier 12. Thus, the lower end 220 is located in the second barrier 12, or under the second barrier 12.

The gate pattern 20 is typically formed by the following successive steps:
a trench is formed beforehand in the stack 1, for example by etching, then
the gate dielectric 22 is formed on the walls and the bottom of the trench, for example by conformal deposition or by oxidation, then
the trench is filled by one or more metal depositions.

Annealing and/or cleaning can be performed before or after some of these steps.

The metal gate 21 can be metal alloy-based, for example gold- and/or platinum- and/or titanium-based. The gate dielectric 22 is typically Al₂O₃ alumina-based. Alternatively, the gate dielectric 22 can be SiN-, or SiO2-, or HFO2-based, for example. The gate dielectric 22 preferably has an almost constant thickness e22 along the walls and the walls and the bottom of the trench.

In the first embodiment illustrated in FIG. 1, the gate pattern 20 passes through the second AlGaN-based barrier 12, and leads to the unintentionally doped GaN layer 13. The second AlGaN-based barrier 12 has, for example, a thickness e12 of around 30 nm The thickness e22 of the gate dielectric 22 is here greater than the thickness e12, such that the lower end 220 is located below the second barrier 12, while the lower end 210 of the gate 21 is located above the second barrier 12. In particular, the depths d210, d10, d12 and d20 are such that d210<d10<d12<d20. At the on-state, the two-dimensional electron gas 101 passes through the second AlGaN-based barrier 12 and extends under the lower end 220, in the unintentionally doped GaN layer 13. The threshold voltage Vth of the transistor is significantly increased, due to the second AlGaN-based barrier 12 to be passed through.

In the second embodiment illustrated in FIG. 2, the gate pattern 20 only partially passes through the second AlGaN-based barrier 12. The second AlGaN-based barrier 12 has, for example, a thickness e12 of around 50 nm. The lower end 220 is thus located within the second AlGaN-based barrier 12. At the on-state, the two-dimensional electron gas 101 extends into the second AlGaN-based barrier 12. It interacts with the second barrier 12 over a distance lesser than in the first embodiment. This can further increase the threshold value Vth of the transistor. As represented in FIG. 2, a second two-dimensional electron gas 102 is typically formed under the second AlGaN-based barrier 12, in the unintentionally doped GaN-based layer 13.

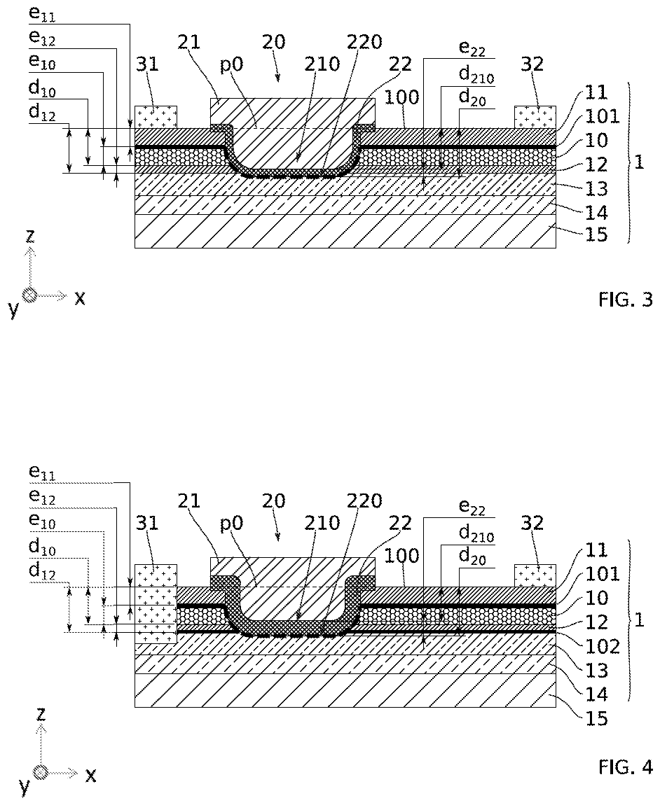

In the third embodiment illustrated in FIG. 3, the gate pattern 20 passes through the second AlGaN-based barrier 12, and leads to the unintentionally doped GaN layer 13.

In this embodiment, the lower end 220 is located below the second barrier 12, and the lower end 210 of the gate 21 is located below the layer 10. In particular, the depths d210, d10, d12 and d20 are such that d10<d210<d12<d20.

In the fourth embodiment illustrated in FIG. 4, the source 31 of the transistor passes through the first and second AlGaN-based barriers 12, and leads to the unintentionally doped GaN layer 13. The source 31 is thus connected to the second two-dimensional electron gas 102 under the second AlGaN-based barrier 12. This makes it possible to improve the electrostatic coupling between the source 31 and the gate 21.

These embodiments can possibly be combined together so as to form another embodiment which is not necessarily illustrated.

Whatever the embodiment considered, the threshold voltage Vth is significantly increased by the effect of the second barrier 12, typically Vth>1V, and even Vth>2V.

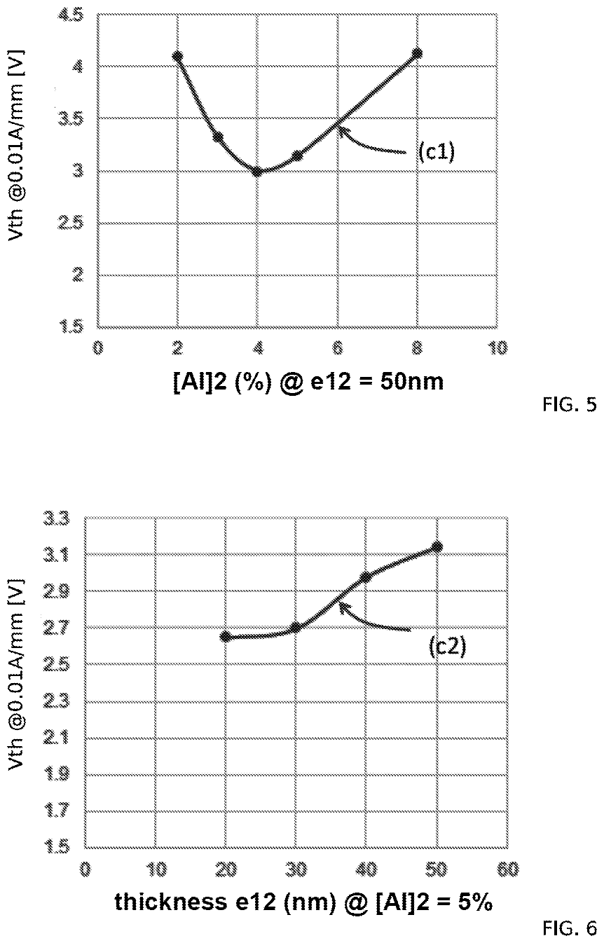

FIGS. 5 and 6 present the evolution of the threshold voltage Vth according to the concentration of aluminium [Al]2 and/or the thickness e12 of the second barrier 12.

As illustrated in FIG. 5, for a thickness e12=50 nm, the threshold voltage Vth is greater than or equal to 3V over the whole concentration range 2% at.≤[Al]≤8% at. A 2% Al ratio makes it possible to obtain a high threshold voltage and a high current level. An 8% Al ratio also makes it possible to obtain a high threshold voltage, but the current level is relatively low. The minimum observed on the Vth curve (c1) of around 5% at. is due to a local minimum of the bottom of the conduction band in AlGaN.

As illustrated in FIG. 6, for a concentration [Al]2=5% at., the threshold voltage Vth is greater than or equal to 2.5V over the whole thickness range 20 nm≤e12≤50 nm. The curve (c2) is monotonous. Thus, the more the thickness e12 increases, the more the threshold voltage Vth increases.

The normally-off 2DEG transistors according to the present invention can be advantageously implemented in power converters, for example DC/AC (direct current/alternating current) DC/DC and AC/DC converters, or also “buck” or “boost” type converters.

The invention is not limited to the embodiments described above.

1-13. (canceled)

14. A GaN-based power transistor, comprising:
a stack of layers in a vertical direction (z), said stack comprising, from an upper surface of said stack:
a first AlGaN-based barrier),
a GaN-based layer, and
a second AlGaN-based barrier; and
a gate pattern comprising:
a metal gate, and
a gate dielectric electrically insulating the metal gate from the stack, the metal gate being in contact with a bottom part and a wall part of the gate dielectric,
said gate pattern passing through the first AlGaN-based barrier, then totally passing through the GaN-based layer and at least partially through the second AlGaN-based barrier, in the vertical direction (z), wherein the second AlGaN-based barrier has a concentration of aluminium [Al]2 of less than or equal to 8% at.

15. The transistor according to claim 14, wherein the gate pattern of the transistor totally passes through the first AlGaN-based barrier, totally passes through the GaN-based layer and at least partially through the second AlGaN-based barrier, without passing through any AlGaN-based barrier other than the first AlGaN-based barrier and the second AlGaN-based barrier.

16. The transistor according to claim 14, wherein the metal gate of the gate patter has an end located at a depth d210 and the second AlGaN-based barrier has a surface located at a depth d12, such that d210 is strictly less than d12, said depths d210 and d12 being taken in the vertical direction from a reference plane (p0) passing by the upper surface of the stack.

17. The transistor according to claim 14, wherein the gate pattern totally passes through the second AlGaN-based barrier in the vertical direction (z).

18. The transistor according to claim 14, wherein the metal gate of the gate pattern has an end at a basal plane (xy) passing within the second AlGaN-based barrier.

19. The transistor according to claim 14, wherein the metal gate of the gate pattern has an end at a basal plane (xy) passing within the GaN-based layer.

20. The transistor according to claim 14, wherein the GaN-based layer separating the second AlGaN-based barrier from the first AlGaN-based barrier, has a thickness e₁₀ greater than or equal to 100 nm.

21. The transistor according to claim 14, wherein the second AlGaN-based barrier has a concentration of aluminum [Al]2 of between 2% at and 8% at.

22. The transistor according to claim 14, wherein the second AlGaN-based barrier has a gradient of concentration of aluminium [Al]2(z) in the vertical direction (z).

23. The transistor according to claim 22, wherein the concentration of aluminium [Al]2 has a Gaussian profile in the vertical direction (z), said profile being centred on half of the thickness e12 of the second barrier.

24. The transistor according to claim 14, wherein the second AlGaN-based barrier has a concentration of aluminum [Al]2 which is constant.

25. The transistor according to claim 14, wherein the second AlGaN-based barrier has a thickness e12 taken in the vertical direction (z) of between 20 nm and 50 nm.

26. The transistor according to claim 14, further comprising a source and a drain on either side of the gate pattern, said source totally passing through the second AlGaN-based barrier in the vertical direction (z).
